(19) United States
(12) Patent Application Publication
(10) Pub. No.: US 2024/0151781 A1
(43) Pub. Date: May 9, 2024

(54) FAILURE DETECTING APPARATUS AND FAILURE DETECTING METHOD

(71) Applicant: DENSO CORPORATION, Kariya-city (JP)

(72) Inventor: Tomomichi MIZOGUCHI, Kariya-city (JP)

(73) Assignee: DENSO CORPORATION, Kariya-city (JP)

(21) Appl. No.: 18/411,554

(22) Filed: Jan. 12, 2024

Related U.S. Application Data
(63) Continuation of application No. PCT/JP2022/024107, filed on Jun. 16, 2022.

(30) Foreign Application Priority Data
Jul. 14, 2021 (JP) 2021-116679

(51) Int. Cl. G01R 31/64

(52) U.S. Cl. CPC G01R 31/64; G01R 31/3644

(57) ABSTRACT

A failure detecting apparatus detects a failure of a capacitor part provided on a communication path. The capacitor part is configured of a plurality of capacitors connected in series so as to cutoff DC current. Also, the failure detecting apparatus is provided with a signal input part that receives a predetermined detection signal from a transmission apparatus via the communication path and a detection part that detects a short-circuit failure of any of the capacitors that constitute the capacitor part based on the detection signal received by the signal input part.

### CROSS-REFERENCE OF RELATED APPLICATIONS

This application is the U.S. bypass application of International Application No. PCT/JP2022/024107 filed on Jun. 16, 2022, which designated the U.S. and claims priority to Japanese Patent Application No. 2021-116679 filed on Jul. 14, 2021, the contents of these are incorporated herein by reference.

### BACKGROUND

### Technical Field

The present disclosure relates to a failure detecting apparatus that detects a short circuit and a failure detecting method thereof.

### Description of the Related Art

Conventionally, according to a battery monitoring apparatus that monitors a battery state such as a voltage for a plurality of battery cells, a configuration is known in which respective battery monitoring apparatuses are connected as a daisy-chain connection to allow monitoring results of the battery monitoring apparatuses to be serially-transmitted. In this case, since the reference voltage (i.e. ground) is different between respective battery monitoring apparatuses, a capacitor as an insulation element is generally provided on the communication line between respective battery monitoring apparatuses in order to restrict the current flowing through the communication line.

### SUMMARY

A failure detecting apparatus according to the present disclosure is provided in a reception apparatus that receives an AC signal from a transmission apparatus via a communication path, detecting a failure of a capacitor part provided on the communication path, wherein the capacitor part is configured of a plurality of capacitors connected in series to cutoff DC current, the failure detecting apparatus including: a signal input part that receives a predetermined detection signal from the transmission apparatus; and a detection part that detects, based on a voltage change amount of the detection signal received by the signal input part, a short-circuit failure of any of the capacitors that constitute the capacitor part.

### BRIEF DESCRIPTION OF THE DRAWINGS

The above-described objects and other objects, features and advantages of the present disclosure will be clarified further by the following detailed description with reference to the accompanying drawings. The drawings are:

FIG. 1 is a block diagram showing a configuration of a battery measurement system;

FIG. 2 is a circuit diagram showing a configuration of a transmission-reception part and a capacitor part;

FIG. 3 is a timing diagram showing an input-output timing of signals in a normal operation;

FIG. 4 is a timing diagram showing an input-output timing of signals in a failure detecting operation;

FIG. 5 is a flowchart of a failure detecting process;

FIG. 6 is a timing diagram showing a charge time and a discharge time;

FIG. 7 is a timing diagram showing a communication method using a Manchester encoding data;

FIG. 8 is a timing diagram showing an input-output timing of signals according to a second embodiment;

FIG. 9 is a timing diagram showing an input-output timing of signals according to the second embodiment;

FIG. 10 is a flowchart showing a failure detecting process according to the second embodiment

FIG. 11 is a diagram showing a configuration of a battery measurement system according to a third embodiment;

FIG. 12 is a circuit diagram showing a configuration of a transmission-reception part and a capacitor part according to the third embodiment;

FIG. 13 is a timing diagram showing a charge time according to the third embodiment; and

FIG. 14 is a diagram showing a configuration of a battery measurement system according to a modification example.

### DETAILED DESCRIPTION OF THE PREFERRED EMBODIMENTS

Conventionally, according to a battery monitoring apparatus that monitors a battery state such as a voltage for a plurality of battery cells, a configuration is known in which respective battery monitoring apparatuses are connected as a daisy-chain connection to allow monitoring results of the battery monitoring apparatuses to be serially-transmitted. In this case, since the reference voltage (i.e. ground) is different between respective battery monitoring apparatuses, a capacitor as an insulation element is generally provided on the communication line between respective battery monitoring apparatuses in order to restrict the current flowing through the communication line.

In the case where a short-circuit failure occurs on the capacitor provided on such a communication line, excessive current or voltage may cause a malfunction in the battery monitoring apparatus. In this respect, a technique is known in which an excessive current is avoided when a short-circuit failure occurs so as to prevent the battery monitoring apparatus from suffering a malfunction.

In this regard, specifically, patent literatures disclose techniques of avoiding excessive current. According to JP-A-2014-222216 discloses a technique in which the communication line is caused to be connected to the reference line (i.e. ground) via a protection element when a short-circuit failure occurs and a voltage exceeding the limit voltage is applied, thereby preventing excessive current from flowing. Further, according to JP-A-2016-114374, a plurality of capacitors are connected in series, whereby an excessive current is prevented from flowing while maintaining the communication even when a short-circuit failure occurs on either one of the capacitors However, with the technique disclosed by JP-A-2014-222216, when a short-circuit failure occurs, the battery monitoring apparatus is unable to communicate with other apparatuses. Then, when battery states cannot be received from the battery monitoring apparatus, for a vehicle having no driving source other than a motor such as electric vehicle, a problem arises that safe operation cannot be ensured and it is not possible for the vehicle to travel.

On the other hand, according to a technique disclosed by JP-A-2016-114374, even when a short-circuit failure occurs on either one capacitor, communication is possible. Hence, the battery states can be received from the battery monitoring apparatuses. However, since communication becomes impossible if short-circuit failures occur on both capacitors, a short-circuit failure has to be detected at a time when a short-circuit occurs on either one capacitor. For this reason, according to the configuration disclosed by JP-A-2016-114374, a failure detecting circuit is provided in order to detect a short-circuit failure of a capacitor by detecting an intermediate voltage between capacitors.

However, according to JP-A-2016-114374, since a failure detecting circuit capable of detecting high voltage is required in addition to the power source monitoring apparatus, a problem arises that the number of components increases, the apparatus becomes more complex and the manufacturing cost increases.

Hereinafter, with reference to the drawings, an embodiment in which a failure detecting apparatus is applied to a vehicle (e.g. electric vehicle) will be described. In more detail, the failure detecting apparatus according to the present embodiment is applied to a reception apparatus that constitutes a battery measurement system for measuring a state of a storage battery. Note that in the following respective embodiments, the same reference symbols are applied to mutually the same or equivalent configurations and the description thereof will be applied to the configurations having the same reference symbols.

### First Embodiment

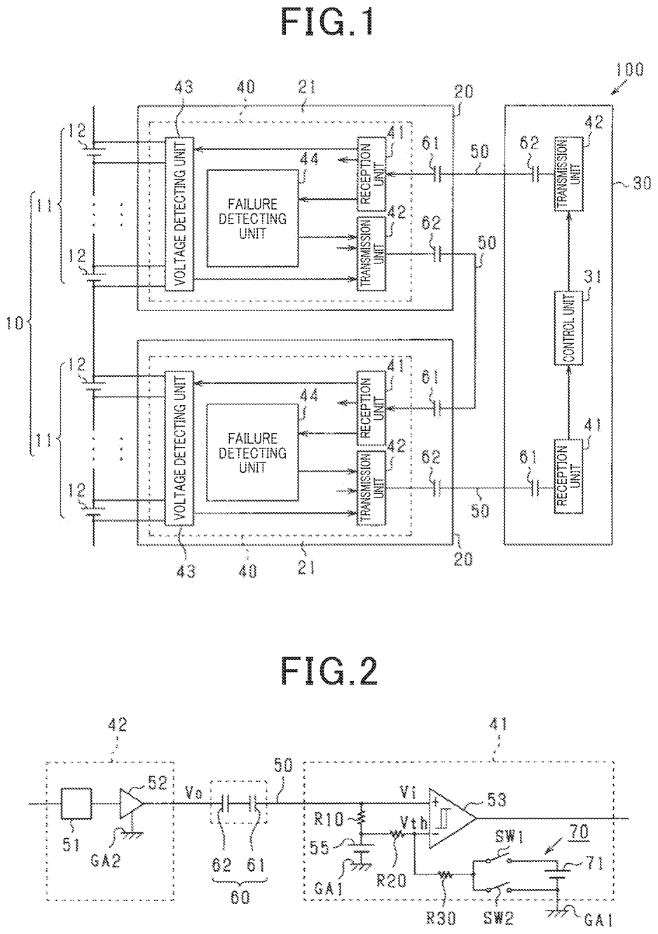

As shown in FIG. 1, a battery measurement system 100 is provided with a battery assembly 10, a battery monitoring unit 20 connected to the battery assembly 10 and an ECU 30 connected to the battery monitoring 20, controlling the battery monitoring unit 20.

The battery assembly 10 is composed of a plurality of battery modules 11 connected in series thereto, having a terminal voltage larger than 100 volts for example. The battery modules 11 are each composed of a plurality of battery cells 12 connected in series. As the battery cell 12, a lithium-ion storage battery or a nickel-hydride storage battery can be utilized.

The battery monitoring unit 20 is provided for each battery module 11 and detects (monitors) a battery state of each battery cell 12. The battery state may include voltage, current SOC, SOH, internal impedance, battery temperature and the like.

In the present embodiment, it is described that voltage is detected as a battery state of each battery state. Further, the battery monitoring unit 20 is not limited to be provided for each battery module 11 but may be provided for a plurality of battery cells 12 or for each battery assembly 10.

The battery monitoring unit 20 is provided with a control substrate 21 on which a supervisory IC 40 or the like are disposed. The battery monitoring unit 20 is connected to an external ECU 30 or other battery monitoring units 20 in a manner of a daisy-chain connection, thereby being communicable of the ECU 30 and other battery monitoring units 20. The battery monitoring units 20 are each determined as a communication source (transmission source, upstream side) or a communication destination (transmission destination, downstream side).

The supervisory IC 40 includes various functions such as a reception unit 41, a transmission unit 42, a voltage detection unit 43 and the like. These functions are accomplished by executing programs stored in a memory unit disposed in the supervisory IC 40 or accomplished by a hardware such as a circuit provided in the supervisory IC 40, or accomplished by both of these, i.e. software (programs) and the hardware circuit.

The reception unit 41 is configured to receive signals from the communication source such as the ECU 30 or other battery monitoring unit 20. With this reception unit 41, the ECU 40 and the supervisory IC 40 serves as a reception apparatus. The transmission unit 42 is configured to transmit signals to the communication destination such as the ECU 30 or other battery monitoring unit 20. With this transmission unit 42, the ECU 30 and the supervisory IC 40 serves as a transmission apparatus.

The voltage detection unit 43 detects, when receiving a control signal indicating a cell selection command that specifies a battery cell 12 as an object to be monitored, voltage of the battery cell 12 to be monitored which is specified by the cell selection command. Then, the voltage detection unit 43 transmits a control signal indicating the detection result via the transmission unit 42.

The ECU 30 includes, similar to the battery monitoring unit 20, a reception unit 41 and a transmission unit 42. Further, the ECU 30 includes a control unit 31 that executes various control operations to monitor the battery state of each battery cell 12 and transmits and receive various control signals. For example, the ECU 30 selects a battery cell 12 to be monitored at a predetermined timing and transmits a cell selection command (control signal) that requires voltage of the selected battery cell 12 to respective battery monitoring units 20. Then, the ECU 30 receives detection result (control signal) of the battery states of respective battery cells 12 and executes an abnormality determination process depending on the detection result.

Next, with reference to FIG. 2, specific configuration of the reception unit 41 and the transmission unit 42 will be described. Here, the reception unit 41 and the transmission unit 42 of the battery monitoring unit 20 will be described as examples, but the reception unit 41 and the transmission unit 42 of the ECU 30 are similar to those of the battery monitoring unit 20.

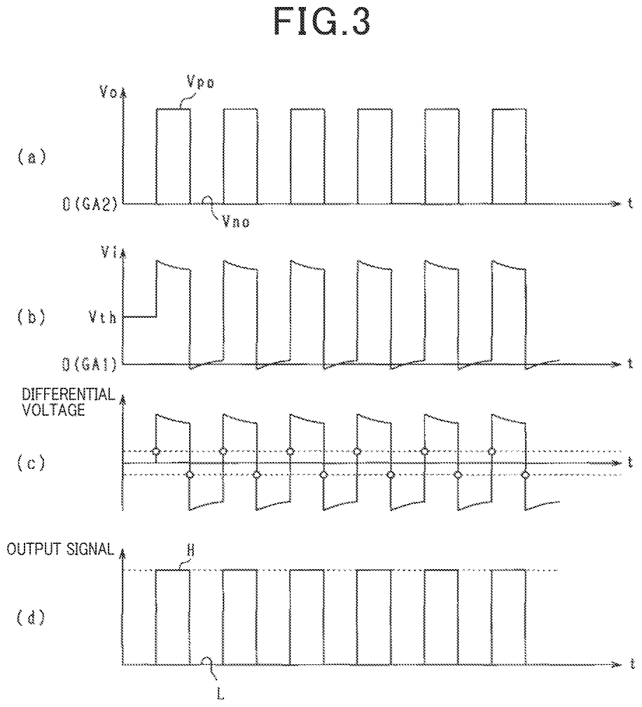

The transmission unit 42 includes an oscillator 51 that generates an AC signal based on the control signal to be transmitted and a buffer 52. The transmission unit 42 is connected to a communication path 50 and connected to the reception unit 42 via the communication path 50. As shown in timing (a) of FIG. 3, the transmission unit 42 is configured to output the AC signal (2 level signal) composed of a high level signal and a low level signal, thereby transmitting the control signal.

The transmission unit 42 is connected to a transmission side ground GA2 and outputs AC signal composed of a high level signal and a low level signal with respect the voltage at the transmission side ground GA2 as a reference (0V). The high level signal is, for example, 5V signal with respect the voltage at the transmission side ground GA2 as a reference (0V), and the low level signal is, for example, 0V signal with respect to the voltage at the transmission side ground GA2 as reference (0V). According to the present embodiment, the AC signal outputted by the transmission unit 42 is indicated by a signal Vo, a high level signal outputted by the transmission unit 42 is indicated by a high level signal Vpo, and the low level signal outputted by the transmission unit 42 is indicated by a low level signal Vno.

The reception unit 41 includes a differential amplifier 53 of which the non-inverting input terminal is connected to the communication path 50. As shown in (b) of FIG. 3, AC signal from the transmission unit 42 is transmitted to the non-inverting input terminal of the differential amplifier 53 via the communication path 50. Also, the inverting input terminal of the differential amplifier 53 receives a threshold voltage Vth generated by a threshold setting circuit. Note that the AC signal transmitted to the non-inverting input terminal of the differential amplifier 53 may be referred to as a signal Vi.

The threshold setting circuit is configured of a series-connected circuit of a resistor RIO and a first auxiliary power source 55 in which the one end is connected to the communication path 50 and the other end is connected to the reception side ground GA1. The inverting input terminal is connected to a connection point between the resistor RIO and the first auxiliary power source 55 via the resistor R20. Hence, the threshold voltage Vth is set such that a voltage of the reception side ground GA1 is the reference (0V). The voltage of the first auxiliary power source 55 ranges between the high level signal Vpo and the low level signal Vno, for example, of 2.5V. According to the present embodiment, the threshold voltage Vth is 2.5V of which the reference voltage is the reception side ground GA1 (0V).

As shown in FIG. 3 (b) and (c), when the input voltage Vi at the non-inverting input terminal is higher than the threshold voltage Vth, that is, the differential voltage between the non-inverting input terminal and the inverting input terminal is higher than a logical inverting threshold as a reference, the differential amplifier 53 determines that a high level signal Vpo is inputted. In this case, the differential amplifier 53 outputs the determination result as shown in FIG. 3 (d) (output high level signal H). Hereinafter, the high level signal outputted by the differential amplifier 53 will be indicated as high level signal H.

Similarly, when the input voltage Vi at the non-inverting input terminal is lower than the threshold voltage Vth, that is, the differential voltage is lower than the logical inverting threshold, the differential amplifier 53 determines that a low level signal is inputted. In this case, the differential amplifier 53 outputs the determination result as shown in FIG. 3 (d) (output low level signal L). Hereinafter, the low level signal outputted by the differential amplifier 53 will be indicated as low level signal L.

Note that the differential amplifier 53 has a hysteresis characteristics. Hence, when the signal at the non-inverting input terminal is higher (or lower) than the threshold Vth, the output logic is inverted. In other word, the low level signal L becomes the high level signal H (or high level signal H becomes the low level signal L). In FIG. 3 (c), the hysteresis characteristics of the logic inversion threshold is indicated by a white circle.

The supervisory IC 40 receives a control signal based on the AC signal composed of high level signal H and low level signal L.

As described above, the transmitting unit 42 is connected to the transmission side ground GA2 and the reception unit 41 is connected to the reception side ground GA1. For example, as shown in FIG. 1, each of the transmission side ground GA2 and the reception side ground GA1 are the negative electrode side voltage of the battery module 11 to which the battery monitoring unit 20 is connected. Hence, the voltage levels corresponding to the transmission side ground GA2 and the reception side ground GA1 are different. Hence, if the transmission unit 42 and the reception unit 41 are directly connected, excessive current flows therebetween due to the voltage difference and may cause a malfunction in the battery monitoring unit 20 such as in the supervisory IC 40 or the ECU 30.

In this respect, a capacitor part 60 as an insulation part that cutoff DC current is provided on the communication path 50, and the transmission unit 42 is connected to the reception unit 41 via the capacitor part 60. The capacitor part 60 is configured of a plurality of series-connected capacitors 61 and 62 (i.e. coupling capacitor as insulation element). As shown in FIG. 1, one capacitor between the capacitors 61 and 62 is mounted on the control substrate 21 of the reception unit 41 side and the other capacitor 62 is mounted on the control substrate 21 of the transmission unit 42 side. Since the capacitor part 60 of the present embodiment is configured of a plurality of series-connected capacitors 61 and 62, even when a short-circuit failure occurs on either one capacitor, DC current can be cut off.

When high level signal Vpo is outputted by the transmission unit, since the high level signal Vpo is higher than the threshold voltage Vth, the capacitors 61 and 62 that constitute the capacitor part 60 are charged. As a result, as shown in timing (b) of FIG. 3, the voltage of signal Vi at the non-inverting input terminal decreases and the differential voltage also decreases as shown in the timing (c) of FIG. 3 (difference with respect to the threshold Vth becomes smaller).

Further, when low level signal Vno is outputted from the transmission unit 42, since the low level signal Vno is lower than the threshold Vth, the capacitors 61 and 62 are discharged. As a result, as shown in the timing (b) of FIG. 3, the voltage of signal Vi at the non-inverting terminal increases and the differential voltage also increases as shown in FIG. 3 (c) (difference with respect to the threshold Vth becomes smaller).

Note that the period of the AC signal (switching period between high level signal Vpo and low level signal Vno) during the communication is designed considering a time constant of charging and discharging in the capacitor part 60. Hence, during a normal operation, erroneous determination caused by a change in the signal Vi due to influence of the capacitor part 60 can be avoided.

In the case where a short-circuit failure occurs on either one of the series-connected capacitors 61 and 62, the total capacitance of the capacitor part 60 becomes large. For example, when the capacitances of the capacitors 61 and 62 are the same, if a short-circuit failure occurs on either one capacitor, the total capacitance of the capacitor part 60 doubles. When the total capacitance of the capacitance part 60 becomes larger, the above-mentioned charge-discharge time constant becomes larger. As a result, a longer time is required for charging and discharging in the capacitor part 60 and the differential voltage is unlikely to change.

According to the present embodiment, with this theory, the supervisory IC 40 is configured to detect, based on an amount of voltage change of the signal Vi applied to the reception unit 41, a short-circuit failure of either capacitor 61 or capacitor 62 that constitutes the capacitor 60. In the following, the configuration will be described in more detail.

As shown in FIG. 1, the supervisory IC 40 is provided with a function of a failure detecting unit 44. The failure detecting unit 44 can be accomplished by both the software and the hardware. The failure detecting unit 44 measures a voltage change amount of the signal Vi at the reception unit 41 and detects the short circuit failure on either capacitor 61 or capacitor 62 based on the detected voltage change amount. The theory of detecting a short-circuit failure based on the voltage change amount will be described in detail. For convenience of explanation, as a detection signal determined in advance, a case will be described in which a high level signal Vpo is outputted from the transmission unit 42. However, the case of a low level signal Vno is the same as above.

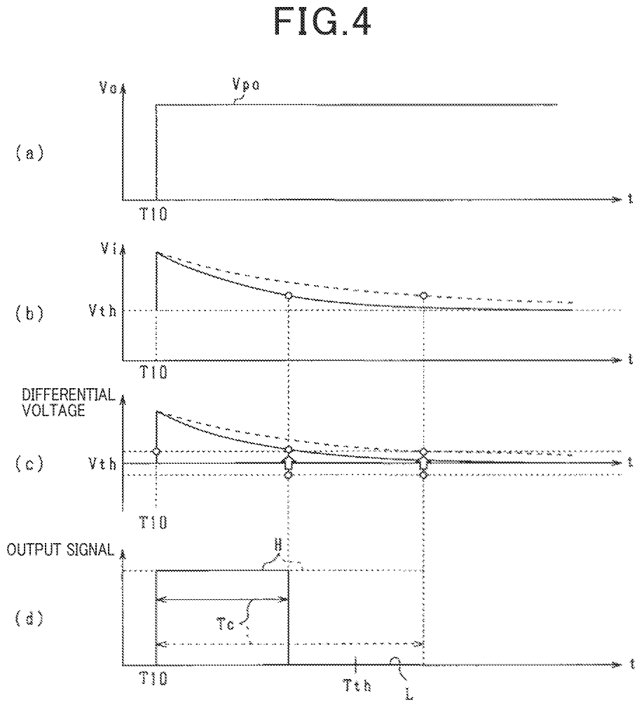

As shown in FIG. 4, when the high level signal Vpo as a detection signal is outputted from the transmission unit 42 at time T10, a state of the signal Vi to be inputted to the reception unit 41 changes.

With this change, at time T10, since the voltage of the signal Vi to be inputted to the differential amplifier 53 is higher than the threshold voltage Vth, the differential amplifier 53 outputs high level signal H to the failure detecting unit 44 as a result of the voltage change.

When the transmission unit 42 continues to output the high level signal Vpo, voltage of the signal Vi at the reception unit 41 changes (decrease) in association with a charging of the capacitor part 60. At this time, the time constant of the charging changes depending on the total capacitance of the capacitor part 60. Specifically, when a short-circuit failure occurs on either capacitor 61 or capacitor 62, the total capacitance increases and the time constant of the charging becomes large. Hence, a period required for the voltage of the signal Vi at the reception unit 41 to change (decrease) to be a prescribed voltage is also changed. Further, the voltage of the signal Vi at the reception unit 41 changes at a prescribed time (that is, an amount of voltage change is different). Note that a state of signal when no short-circuit failure is present is indicated by a solid line in FIG. 4 and a state of signal when a short-circuit failure is present is indicated by a dotted line in FIG. 4.

According to the present embodiment, it is determined whether a period required for the voltage of the signal Vi at the reception unit 41 to change (decrease) to be a prescribed voltage is larger than a predetermined period Tth, whereby an amount of voltage change is determined and a short-circuit failure is detected. In other words, even when the transmission unit 42 continues to output the high level signal Vpo, the voltage of the signal Vi at the reception unit 41 eventually decreases to a threshold voltage Vth in association with the charging of the capacitor part 60. Therefore, a period is measured from a time when the transmission unit 42 outputs the high level signal Vpo as a detection signal to a time when the differential amplifier 53 outputs the low level signal L, and it is determined whether the measured period is longer than a predetermined period Tth, thereby detecting a short-circuit failure.

However, generally, a period required for the voltage of the signal Vi at the reception unit 41 to decrease to reach the threshold voltage Vth in association with the charging of the capacitor part 60 is longer. In this respect, according to the present embodiment, in the case where a failure diagnostic test is conducted, the threshold voltage Vth of the differential amplifier 53 is changed. Specifically, when the transmission unit 42 is caused to output the high level signal Vpo in order to perform a failure detection, the threshold voltage Vth of the differential amplifier 53 is changed to be a first threshold Vth1 which is higher than the threshold voltage Vth by a predetermined value. In FIG. 4, a white arrow indicates a case where the logical threshold value (indicated by a white circuit) is changed taking hysteresis characteristics into consideration. In the case where the transmission unit 42 is caused to output the low level signal Vno in order to perform a failure detection, similar to the above, the threshold voltage Vth of the differential amplifier 53 is changed to be a second threshold Vth2 which is lower than the threshold voltage Vth by a predetermined value. The first threshold voltage Vth1 and the second threshold voltage Vth2 are set by an experiment or the like taking the time constant and a predetermined period Tth into consideration.

Thus, in the case where the failure detection is performed, the differential amplifier 53 is configured to output a low level signal L when the voltage of the signal Vi is lower than or equal to the first threshold voltage Vth1. In other words, the failure detecting unit 44 determines that a short-circuit failure has occurred when determined that a period from a time when high level signal Vpo is outputted to a time when the low level signal L is outputted (corresponding to a charge time Tc) is larger than the predetermined period Tth. On the other hand, the failure detecting unit 44 determines that a short-circuit failure has not occurred when determined that a period from a time when high level signal Vpo is outputted to a time when the low level signal L is outputted (corresponding to a charge time Tc) is smaller than the predetermined period Tth.

Next, an example of a threshold changing circuit 70 will be described. The threshold changing circuit 70 for changing the threshold voltage Vth is provided in the reception circuit 41 as shown in FIG. 2. The threshold changing circuit 70 is provided with a first switch SW1, a second switch SW2 and a second auxiliary power source 71.

The positive electrode of the second auxiliary power source 71 is connected to a first end between both ends of the resistor 30 via a first switch SW1. Similarly, the negative electrode of the second auxiliary power source 71 is connected to a first end of the resistor R30 via the second switch SW2. The second auxiliary power source 71 is configured to be capable of outputting a voltage across the terminals (also referred to as terminal voltage: e.g. 5.0V) which is higher than the terminal voltage (e.g. 2.5V) of the first auxiliary power source 55. The second auxiliary power source 71 is grounded to the reception side ground GA1. The second end of the resistor 30 is connected to a portion between the resistor R20 and the non-inverting input terminal.

Then, the first switch SW1 is turned ON and the second switch SW2 is turned OFF, whereby the first threshold voltage Vth.1 which is higher than the threshold voltage Vth is applied to the non-inverting input terminal of the differential amplifier 53. Moreover, the first switch SW1 is turned OFF and the second switch SW2 is turned OFF, whereby the second threshold voltage Vth2 which is lower than the threshold voltage Vth is applied to the non-inverting input terminal of the differential amplifier 53. That is, the first switch SW1 is turned ON to change the threshold Vth to be the first threshold voltage Vth1, and the second switch SW2 is turned ON to change the threshold voltage Vth to be the second threshold Vth2. Note that the threshold changing circuit 70 is an example, and the circuit configuration thereof may be arbitrarily changed.

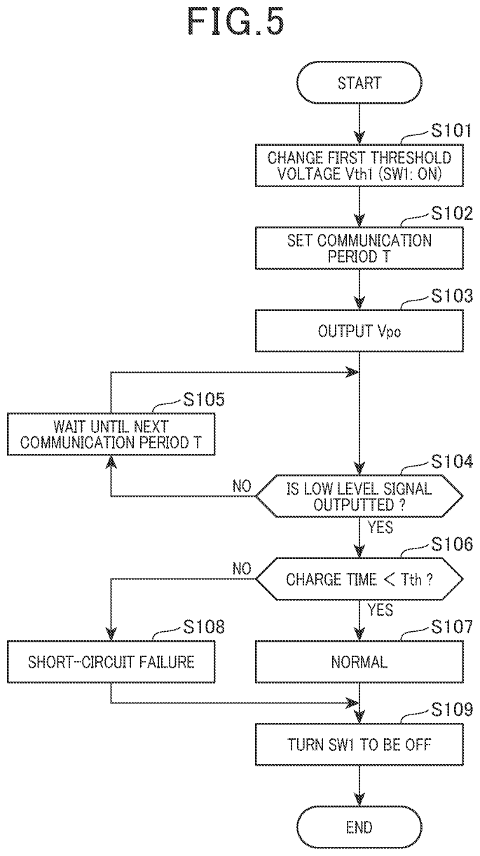

Next, a failure detecting process executed by a failure detecting unit 44 will be described with reference to FIG. 5. The failure detecting process is executed at a predetermined execution timing, for example, executed when activating the power source and the like. The failure detecting process shown in FIG. 5 performs a failure detection by outputting the high level signal Vpo as a detection signal from the transmission unit 42. The case of the low level signal Vno is similar to that of the high level signal Vpo, the explanation thereof will be omitted. In the following explanation, it is assumed that the low level signal Vno is outputted from the transmission unit 42 when the failure detecting process is activated, and assumed that a charge-discharge current stably flows (AC signal flows) to the capacitor part 50 to be charged or discharged before activating the failure detecting process.

The failure detecting unit 44 starts to execute the failure detecting process at a predetermined execution timing and turns the first switch SW1 of the threshold changing circuit 70 (step S101). Thus, the threshold voltage Vth at the inverting input terminal of the differential amplifier 53 is changed to the first threshold voltage Vth1.

Next, failure detecting unit 44 sets a communication period T (step S102). Then, the failure detecting unit 44 commands the transmission unit 42 as the communication source to output the high level signal Vpo as the detection signal (step S103).

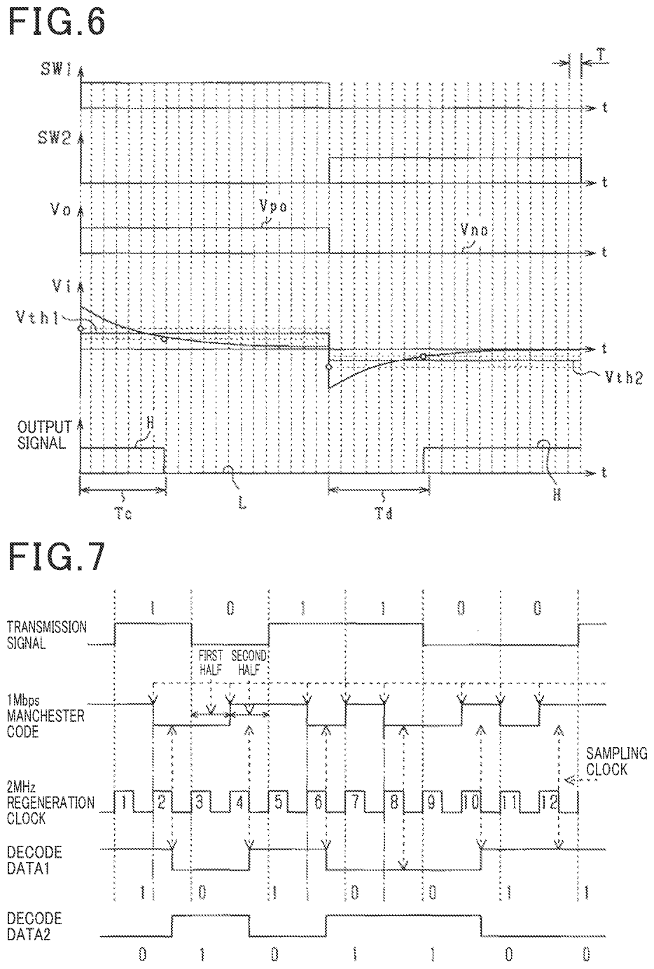

Thus, as shown in FIG. 6, the transmission unit 42 outputs the high level signal Vpo, then, voltage of the signal Vi at the non-inverting input terminal of the differential amplifier 53 becomes higher than the first threshold voltage Vth1, and the differential amplifier 53 outputs the high level signal H to the failure detecting unit 44. As described above, since the differential amplifier 53 has hysteresis characteristics, the high level signal H is actually outputted when the voltage Vi of the signal Vi becomes higher than the first threshold Vth1 by a predetermined value.

Next, as shown in FIG. 5, the failure detecting unit 44 determines whether a low level signal L is outputted from the differential amplifier 53 (step S104). When the determination result is negative, the failure detecting unit 44 again executes the process at step S104 after the communication period has elapsed. That is, the failure detecting unit 44 determines whether the differential amplifier 53 outputs the low level signal at each communication period T.

Meanwhile, the transmission unit 42 continues to output the high level signal Vpo. Hence, as shown in FIG. 6, the capacitor part 60 is charged and the voltage of the signal Vi at the non-inverting input terminal of the differential amplifier 53 is gradually lowered. Then, when the voltage of the signal Vi at the non-inverting input terminal of the differential amplifier 53 becomes lower than or equal to the first threshold voltage Vth1, the differential amplifier 53 outputs the low level signal to the failure detecting unit 44. As described above, since the differential amplifier 53 has hysteresis characteristics, the low level signal L is outputted when the voltage of the signal Vi actually decreases below the first threshold voltage Vth1 by a predetermined value.

In the case where the determination result at step S104 is positive, the failure deterring unit 44 acquires a period from a time when the high level signal Vpo is outputted to a time when the low level signal L is outputted (charge time Tc) and determines whether the charge time Tc is shorter than the predetermines period Tth (step S106). In FIG. 6, a charge time Tc is shown. When the failure detection is performed by outputting the low level signal Vno, a period from a time when the low level signal Vno is outputted to a time when the high level signal H is outputted (discharge time Td) is measured.

As shown in FIG. 5, when the determination result at step S106 is affirmative (shorter), the failure detecting unit 44 determines that the capacitor part 60 is normal (step S107). On the other hand, when the determination result at step S106 is negative, the failure detecting unit 44 determines that a short-circuit failure has occurred on either the capacitor 61 or the capacitor 62 (step S108).

After completing the processes at steps S107 and S108, the failure detecting unit 44 turns the first switch SW1 of the threshold changing circuit 70 to be OFF (step S109). Thus, the threshold voltage Vth is inputted to the inverting input terminal of the differential amplifier 53. Further, the failure detecting unit 44 commands the transmission unit 42 as the communication source to stop the outputting the high level signal Vpo. Thereafter, the failure detecting unit 44 terminates the failure detecting process. When the process detects a short-circuit failure at step S108, the failure detecting unit 44 performs, after completing the failure detecting process, processes related to the short-circuit failure such as notification to the ECU 30 of an occurrence of the short-circuit failure.

According to the present embodiment, the supervisory IC 40 having the failure detecting unit 44 that performs the failure detecting process corresponds to failure detecting apparatus. According to the above-described embodiments, the control unit 31 of the ECU 30 may include a failure detecting unit 44 and cause the failure detecting unit to perform a failure detecting process. In this case, the ECU 30 corresponds to failure detecting apparatus.

Further, according to the above-described embodiments, the reception unit 41 corresponds to signal input unit that receives detection signal. Also, the failure detecting unit 44 corresponds to detection unit that detects a short-circuit failure on the capacitor 61 and 62. The differential amplifier 53 corresponds to signal determination unit. Also, the threshold changing circuit 70 corresponds to threshold setting unit. Moreover, step S103 of the failure detecting process corresponds to signal input step, steps S104 to S108 correspond to detection step that detects a short-circuit failure of capacitors 61 and 62.

With the configuration of the above-described embodiments, significant effects and advantages can be obtained as follows.

The capacitor part 60 is configured of a plurality of capacitors 61 and 62 which are connected in series. When a short-circuit failure occurs on either capacitor 60 or capacitor 61, the total capacitance of the capacitor 60 becomes large and the time constant of charging or discharging becomes larger. As a result, when a predetermined detection signal is outputted, the voltage of the signal Vi which is received by the reception unit 41 gradually changes.

In this respect, the failure detecting unit 44 is configured to detect a short-circuit failure of any one of the capacitors 61 and 62 based on the voltage change amount of the voltage of the signal Vi received by the reception unit 41. Thus, a circuit for a failure detection is not required in the battery monitoring unit 20 in the reception side so that a failure detection can be accomplished by a simple configuration. Note that a cutoff state of the DC current can be maintained even if a short-circuit failure occurs on either the capacitor 61 or 62.

The failure detecting unit 44 determines that a short-circuit failure has occurred in the case where a period from when the high level signal Vpo (or low level signal Vno) is caused to be outputted to a time when a voltage change amount reaches a predetermined amount is larger than or equal to a predetermined period Tth. Thus, sensors for detecting voltage of the signal Vi are not required so that a failure detection can be accomplished by a simple configuration.

More specifically, the failure detecting unit 44 measures, during the high level signal Vpo being outputted from the transmission unit 42, a period (charge time Tc) from when the high level signal Vpo is caused to be outputted to a time when the low level signal L is outputted, and determines that a short-circuit failure has occurred when the measured period is larger than or equal to the predetermined period Tth. Similarly, the failure detecting unit 44 measures, during the low level signal Vno being outputted from the transmission unit 42, a period (discharge time Td) from when the low level signal Vno is caused to be outputted to a time when the high level signal H is outputted, and determines that a short-circuit failure has occurred when the measured period is larger than or equal to the predetermined time Tth. Thus, the charge time Tc (or discharge time Td) corresponding to the voltage change amount is measured based on a signal determination of the differential amplifier 53 of the reception unit 41 and a short-circuit failure is detected based on the charge time Tc (discharge time Td). In other words, a signal determination used for the communication is utilized without using a dedicated apparatus (e.g. circuit elements or sensors) for detecting a short-circuit failure, whereby a short-circuit failure can be detected.

The threshold changing circuit 70 is provided to change the threshold voltage Vth. Specifically, in the failure detection, when the high level signal Vpo as the detection signal is outputted from the transmission unit 42, the threshold voltage Vth is changed to be a first threshold voltage Vth1 which is higher than the threshold voltage Vth. On the other hand, when the low level signal Vno as the detection signal is outputted from the transmission unit 42, the threshold voltage Vth is changed to be a second threshold voltage Vth2 which is lower than the second threshold voltage Vth2. With this configuration, in the failure detection, comparing to a case where the threshold voltage Vth is not changed, the charge time Tc and the discharge time Td can be shorter such that the determination can be made promptly.

### Second Embodiment

The configuration of the above-described first embodiment can be modified like a second embodiment as below. In the followings, configurations different from those in the above-described embodiments will be described. Further, according to the second embodiment, as a fundamental configuration, the battery measurement system 100 of the first embodiment will be described as an example.

The reception unit 41 and the transmission unit 42 according to the second embodiment perform a communication therebetween using Manchester encoding data. An overview of the Manchester encoding data will be described. FIG. 7 illustrates a method of decoding the Manchester encoding data. Manchester encoding refers to a code in which s rectangular wave pattern ‘10’ is assigned to binary number 1 where the one period corresponds to a bit period, and a rectangular pattern ‘01’ of which the phase is 180° different from the above rectangular pattern is assigned to a binary number 0. Accordingly, in the case where the binary data is decoded from the Manchester encoding data, if a first half or a second half of the bit period of the Manchester encoding data can be detected, it can be determined that the data indicates either 1 or 0.

Hence, decode data is acquired in the following manner. When reproducing a decode clock (regeneration clock) using a changing point of the Manchester encoding data, after synchronizing the phase to the changing point of the Manchester encoding data, with a sampling clock (clock timing) corresponding to either one of the first half or the second half of the bit period of the Manchester encoding data is utilized, information appearing in sampling clock is acquired, thereby acquiring the decode data.

For example, as shown in FIG. 7, in the case where the decode data is acquired from the second half of the bit period of the Manchester code transmitted at 1 Mbps rate, the decode data is acquired in the following manner. A regeneration clock having a doubled frequency (2 MHz) relative to that of the Manchester encoding data is synchronized to this encoding data, then a sampling clock corresponding to the second half of the bit period is selected among two types of odd and even clock timing which constitute the regeneration clock and the Manchester encoding data is sampled by the selected sampling clock, thereby acquiring the decode data. In the case shown in FIG. 7, since the clock corresponding to the second half of the bit period is even number clock, this clock is selected to be the sampling clock. As a result, the decode data 1 is acquired. Actually, the polarity of the decode is inverted, thereby obtaining the decode data 2 (output result, logical result).

In the case where the Manchester encoding data is utilized, the transmission unit 42 continues to always output the high level signal Vpo and the low level signal Vno alternately. Hence, when performing the failure detection like the first embodiment, only either one signal cannot be continuously outputted over a plurality of periods.

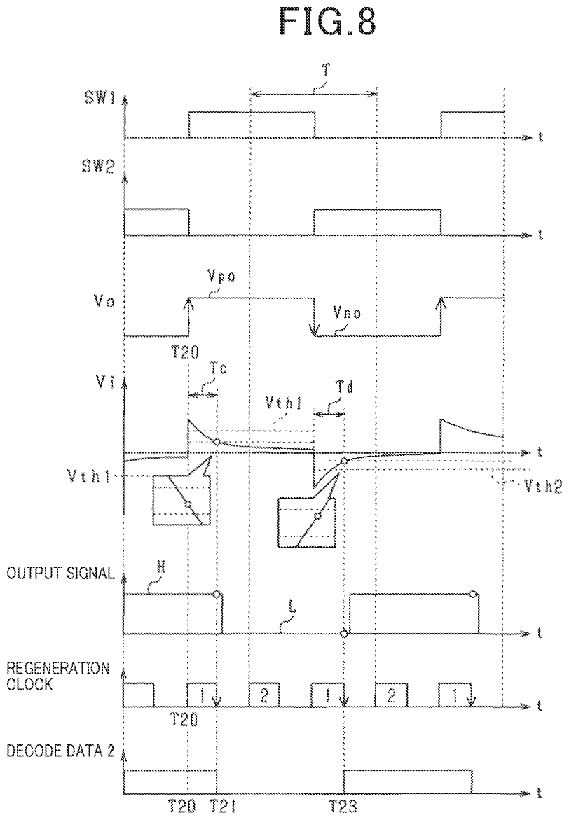

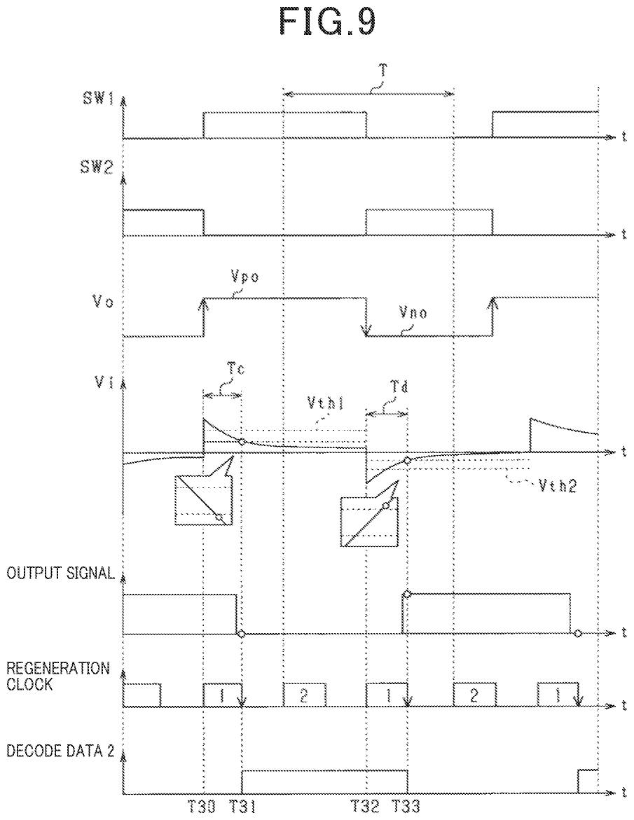

In this respect, according to the second embodiment, the communication period T is changed as described below, thereby measuring the charge time Tc and the discharge time Td. The method for measuring the charge time Tc and the discharge time Td will be described in accordance with FIGS. 8 and 9. FIG. 8 is a timing diagram showing a case where ¼ period of the communication period T is shorter than the charge time Tc (or discharge time Td). FIG. 9 is a timing diagram showing a case where ¼ period of the communication period T is longer than the charge time Tc (or discharge time Td). In FIGS. 8 and 9, it is described assuming that the decode data is acquired in the second half of the communication period T. In other words, in the case shown in FIGS. 8 and 9, since the regeneration clock corresponding to the second half thereof is odd number clock, this odd number clock is selected as a sampling clock.

In FIGS. 8 and 9, the transmission unit 42 alternately outputs the high level signal Vpo and the low level signal Vno as the detection signal. Due to this, the switches SW1 and SW2 are alternately turned to be ON and OFF. Thus, the signal Vi inputted to the reception unit 41 becomes higher than the first threshold voltage Vth1 at a timing (timings T20, T30) where the high level signal Vpo is outputted from the transmission unit 42. Note that high level signal H is outputted from the differential amplifier 53 at least these timings T20 and T30.

The regeneration clock is set at a transition timing (timings T20 and T30) from the low level signal Vno to the high level signal Vpo. In accordance with the regeneration clock, the failure detecting unit 44 reads the signal (high level signal H or low level signal L) outputted from the differential amplifier 53 to be the decode data 1 at a time when ¼ period of the communication period T elapsed (sampling clock (timings T21, T31)). Then, the failure detecting unit 44 inverts the polarity of the decode data 1 and acquires the decode data 2 (output result, logical result). Thus, the failure detecting unit 44 has a function of a logic determination unit.

In FIG. 8, on the assumption, the voltage of the signal Vi is not lower than or not equal to the first threshold voltage Vth1 at a timing T21 of the sampling clock (more specifically, voltage not lower than the first threshold Vth1 by a predetermined value in accordance with hysteresis characteristics). Hence, the differential amplifier 53 outputs the high level signal H as the decode data 1. For the final decode data 2, the polarity of the decode data 1 is inverted and becomes the low level signal (logic L).

On the other hand, in FIG. 9, on the assumption, the voltage of the signal Vi is lower than or equal to the first threshold voltage Vth1 at a timing T31 of the sampling clock (more specifically, voltage lower than the first threshold Vth1 by a predetermined value in accordance with hysteresis characteristics). Hence, the differential amplifier 53 outputs the low level signal L as the decode data 1. For the final decode data 2, the polarity of the decode data 1 is inverted and becomes the high level signal (logic H).

As described above, the communication period T is gradually changed, whereby the signal to be inputted is inverted. The timing at which the signal is inverted equals to a timing at which the ¼ period of the communication period T matches the charge time Tc. Hence, the failure detecting unit 44 is able to identify the charge time Tc based on the communication period T corresponding to the timing at which the signal is inverted. For the case of the discharge time Td, it can be identified similarly.

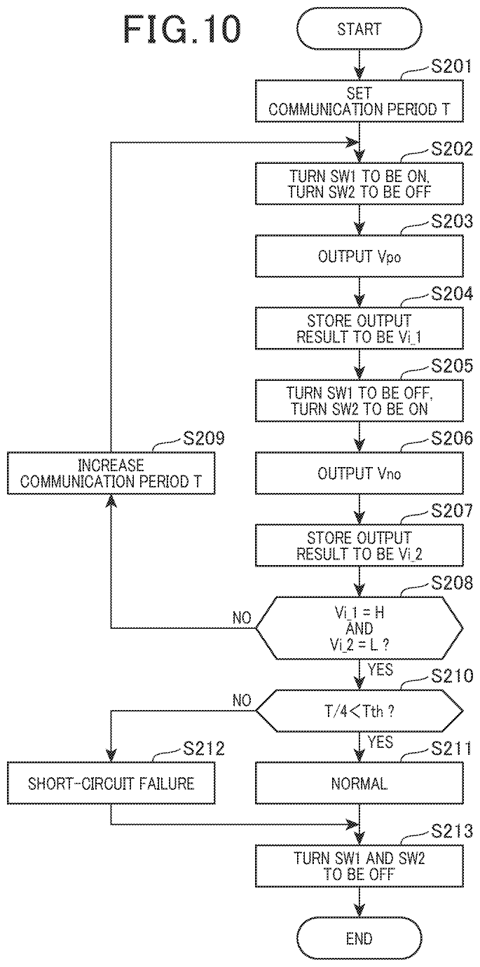

Hereinafter, with reference to FIG. 10, a failure detecting process according to the second embodiment will be described.

The failure detecting unit 44 firstly sets an initial value to the communication period T (step S201). The initial value is preferably be set such that its ¼ period is reliably shorter than the charge time Tc (or discharge time Td).

Next, the failure detecting unit 44 turns the first switch SW1 to be ON and turns the second switch SW2 to be OFF (step S202). Thus, the threshold voltage Vth to be inputted to the inverting input terminal of the differential amplifier 53 is changed to be the first threshold voltage Vth1.

Next, the failure detecting unit 44 commands the transmission unit 42 as the communication source to output the high level signal Vpo as the detection signal (step S203). In other words, the failure detecting unit 44 commands the transmission unit 42 to turn the low level signal Vno to be high level signal Vpo. Then, the failure detecting unit 44 acquires the output result (decode data 2) from the differential amplifier 53 with the sampling clock (step S204). The failure detecting unit 44 stores the output result as a reception signal Vi_1. As shown in FIGS. 8 and 9, as long as the signal Vi is not lower than the first threshold Vth1 due to the voltage change (more specifically, voltage lower than the first threshold Vth1 by a predetermined value based on the hysteresis characteristics, the same shall apply hereinafter), logic L is acquired as the decode data 2, and when the signal Vi becomes below the first threshold value Vth1, the logic is inverted and the logic H is acquired.

Next, the failure detecting unit 44 turns the first switch SW1 to be OFF and turns the second switch to be ON at a change timing in the communication period T (step S205). Thus, the threshold voltage Vth inputted to the inverting input terminal of the differential amplifier 53 is changed to be the second threshold voltage Vth2.

Next, the failure detecting unit 44 commands the transmission unit 42 as the communication source to output the low level signal Vno (step S206). In other words, the failure detecting unit 44 commands the transmission unit 42 to turn the high level signal Vpo to be low level signal Vno at the change timing in the communication period T in order to output the logic H as the decode data 2. Then, the failure detecting unit 44 reads the output result (decode data 2) from the differential amplifier 53 with the sampling clock (step S207). The failure detecting unit 44 stores the output result as the reception signal Vi_2. As shown in FIGS. 8 and 9, as long as the signal Vi is not higher than the second threshold Vth2 due to the voltage change (more specifically, voltage higher than the second threshold Vth2 by a predetermined value based on the hysteresis characteristics, the same shall apply hereinafter), logic H is acquired as the decode data 2, and when the signal Vi is higher than the second threshold value Vth2, the logic is inverted and the logic L is acquired.

Then, the failure detecting unit 44 determines whether the reception signal Vi_1 is logic H and the reception signal Vi_2 is logic L (step S208). That is, the failure detecting unit 44 determines whether the output result does not correspond to the signal Vo outputted from the transmission unit 42. In other words, it is determined whether the reception signal Vi_1 is logic H despite logic L being required to be outputted as the decoded data 2, and the reception signal Vi_2 is logic L despite logic H being required to be outputted as the decode data 2, and whether the logic in inverted.

In the case where the determination result is negative (not inverted), the failure detecting unit 44 adds an increase time Δ to the previous communication period T, thereby setting new communication period T (step S209). Then, the failure detecting unit 44 again performs processes step S202.

On the other hand, when the determination result at step S208 is affirmative (inverted), the failure detecting unit 44 determines whether ¼ period of the communication period T which has been set is less the predetermined period Tth (step S210). In other words, the failure detecting unit 44 determines, when the signal Vo outputted from the transmission unit 42 does not correspond to the output result (inverted), that ¼ period of the communication period T currently set corresponds to the charge time Tc (or discharge time Td), and determines whether ¼ period of the communication period T is less than the predetermined period Tth.

When the determination result at step S210 is affirmative, the failure detecting unit 44 determines that it is in normal state (step S211), and when the determination result is negative the failure detecting unit 44 detects a short-circuit failure (step S212). After performing the processes at steps S211 and 212, the failure detecting unit 33 turn the first switch SW1 and the second switch SW2 to be OFF (step S213). That is, the threshold voltage Vth is caused to be inputted to the inverting input terminal of the differential amplifier 53. Then, the failure detecting unit 44 terminates the failure detecting process.

According to the above-described embodiments, the following significant effects and advantages can be obtained.

The failure detecting unit 44 gradually changes the communication period T to change a period from a time when the signal Vo of the transmission unit 42 is caused to be changed to a sampling time (sampling clock) at which the output result of the differential amplifier 53 is acquired. Thus, the failure detecting unit 44 identifies a timing at which the output result is inverted and identifies a period required for the voltage change amount to reach a predetermined amount (charge time Tc and discharge time Td) by setting the communication period T of the inversion timing to be ¼.

Thus, even in the case where either high level signal Vpo or low level signal Vno cannot be continuously outputted like a case of Manchester encoding data, the charge time Tc (or discharge time Td) can be identified based on the communication period T. Hence, without adding a dedicated circuit, a failure detecting can be achieved with a simple configuration.

### Third Embodiment

The configuration of the above-described first embodiment may be modified in the third embodiment as follows. Hereinafter, according to the third embodiment, configurations different from those in the above-described embodiments will be described. Further, according to the third embodiment, as a fundamental configuration, the battery measurement system 100 of the first embodiment will be described as an example.

According to the third embodiment, a differential communication is conducted between the transmission unit 42 and the reception unit 41. Hereinafter, a configuration for performing a differential communication and a failure detecting method when performing the differential communication will be described.

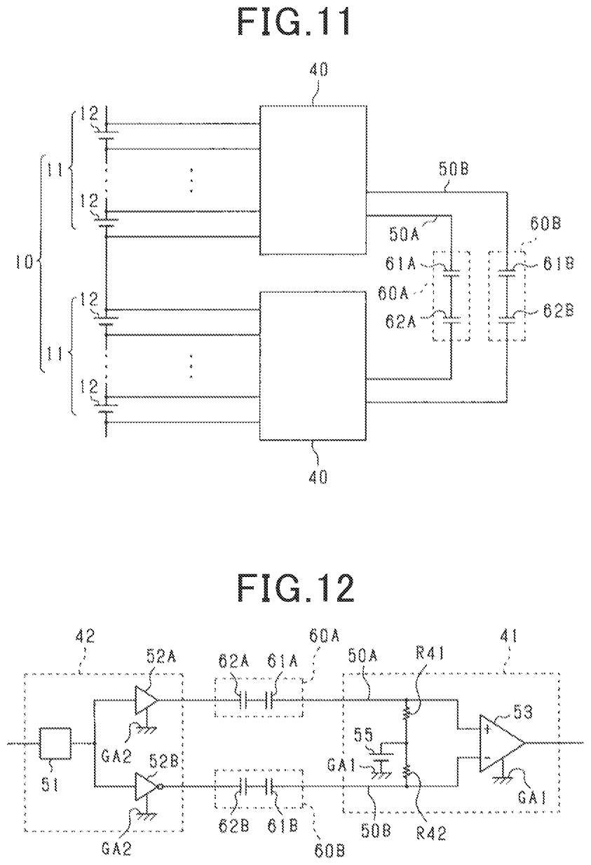

As shown in FIG. 11, according to the third embodiment, a pair of communication paths 50A and 59B are provided between the transmission unit 42 and the reception unit 41. In the respective communication paths 50A and 50B, similar to the first embodiment, capacitor parts 60A and 60B are provided respectively.

As shown in FIG. 12, the communication path 50A is connected to the non-inverting input terminal of the differential amplifier 53 and the communication path 50B is connected to the inverting input terminal of the differential amplifier 53. In the reception unit 41 side, a series-connection part where a plurality of resistors R41 and R42 are connected in series is provided between the communication path 50A and the communication path 50B. The positive electrode of the first auxiliary power source 55 is connected to a connection point between the resistor R41 and the resistor R42 and the negative electrode is connected to a reception side ground GA1.

As shown in FIG. 12, the capacitor part 60A of the communication path 50A is connected in series to the capacitor part 60B of the conduction path 50B. Hence, similar to the first embodiment, the failure detecting unit 44 measures the voltage change amount of the signal Vi inputted to the reception unit 41, and detects a short-circuit failure of any of capacitors 61A, 61B, 62A and 62B.

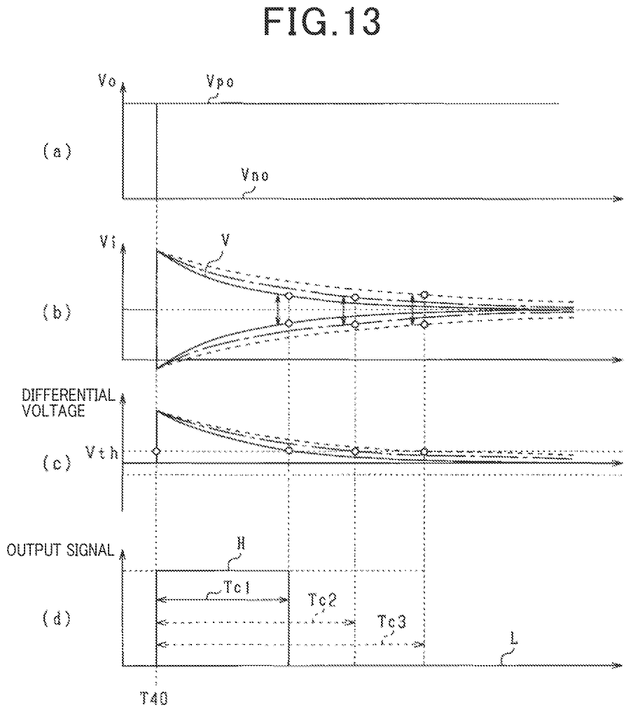

More specifically, as shown in FIG. 13, in the case where the high level signal Vpo is outputted via the communication path 50A and the low level signal Vno is outputted via the communication path 50B at the time T40 from the transmission unit 42, the signal Vi to be inputted to the reception unit 41 changes. With this change, at time T40, since the differential voltage based on the signal Vi to be inputted to the differential amplifier 53 becomes higher than the threshold voltage Vth, the differential amplifier 53 outputs the high level signal H to the failure detecting unit 44. The differential amplifier 53 according to the third embodiment does not have hysteresis characteristics.

When the transmission unit 42 continues to output the high level signal Vpo, the voltage of the signal Vi at the reception unit 41 changes in association with the charging to the capacitor parts 60A and 60B, and the differential voltage decreases. At this time, the time constant of the charging is changed depending on the capacitor parts 60A and 60B. Specifically, when a short-circuit failure occurs on any of capacitors 61A, 61B, 62A and 62B, the total capacitance increases and the time constant of the charging becomes large. Note that when short circuit failures occur on a plurality of capacitors 61A, 61B, 62A and 62B, the total capacitance becomes even larger and the time constant of the charging becomes even larger.

Hence, a time required for the differential voltage to change (decrease) to be a prescribed voltage varies. Otherwise, the differential voltage varies at a prescribed time (that is, voltage change amount varies). Specifically, as shown in FIG. 13, when a short-circuit failure occurs on any of capacitors 61A, 61B, 62A and 62B, a time required for the differential voltage to change (decrease) to be a prescribed voltage becomes longer. At this moment, when short-circuit failures occur on a plurality of capacitors 61A, 61B, 62A and 62B, a time required for the differential voltage to change (decrease) to be a prescribed voltage becomes longer.

In FIG. 13, the differential voltage or the like in the case where no short-circuit failure occurs on the capacitors 61A, 61B, 62A and 62B will be indicated by a solid line. Further, the differential voltage or the like in the case where a short-circuit failure occurs on any one of the capacitors 61A, 61B, 62A and 62B will be indicated by a one-dot chain line. Furthermore, the differential voltage or the like in the case where a short-circuit failure occurs on any one of the capacitors 61A and 62A, and a short-circuit failure occurs on any one of capacitors 61B and 62B will be indicated by a dotted line.

According to the present embodiment, it is determined whether a time required for the differential voltage to decrease to reach a threshold voltage Vth (charging time Tc1, Tc2 and Tc3) is longer than a predetermined time Tth, thereby determining an amount of voltage change (voltage change amount) to detect occurrence of a short-circuit failure. In other words, even when the transmission unit 42 continues to output the high level signal Vpo, the differential voltage eventually decreases to be the threshold voltage Vth in association with the charging to the capacitors 60A and 60B. At this time, the differential amplifier 53 outputs the low level signal L.

In this respect, according to the present embodiment, the failure detecting unit 44 causes the transmission unit 42 to output the high level signal Vpo via the communication path 50A and the low level signal Vno via the communication path 50B and then measures a time required for receiving the low level signal from the differential amplifier 53 (charge time Tc1, Tc2 and Tc3 shown in FIG. 13). Then, the failure detecting unit 44 determines whether the measured time is longer than the predetermined time Tth, thereby detecting a short-circuit failure. Thus, with a simple configuration, a failure detection can be accomplished.

At this moment, the failure detecting unit 44 may detect short-circuit failure on some of the capacitors 61A, 61B, 62A and 62B based on difference between the measured time. For example, the failure detecting unit 44 determines, when determining that the measured time is longer than the second predetermined time Tth2 (second predetermined time Tth2>predetermined time Tth), that a short-circuit failure occurs on any one of the capacitors 61A and 62A and any one of the capacitors 61B and 62B. Hence, the number of capacitors in which a short-circuit failure occurs can be identified. In other words, the failure detecting unit 44 is able to determine whether a short-circuit failure occurs on both the communication paths 50A and 50B or whether a short-circuit failure occurs on either one of the communication paths 50A and 50B.

### Modification Example

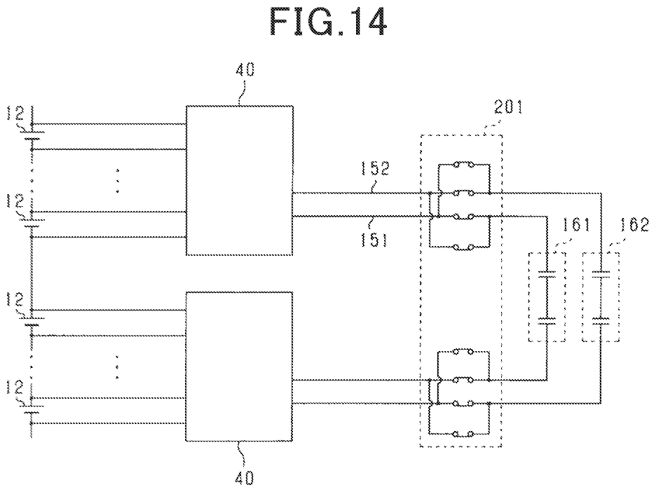

According to the above-described first embodiment, as shown in FIG. 14, a plurality of communication paths 151 and 152 may be provided between the transmission unit 42 and the reception unit 41. At this time, either one communication path in the plurality of communication paths 151 and 152 may be a clock line, for example. In this case, a selection circuit 201 may be provided as a selection unit for selecting the communication paths 151 and 152 with which a failure is detected. Then, the failure detecting unit 44 may select a communication path with which a failure detection is conducted from the communication paths 151 and 152 and then detect a short-circuit failure in the capacitors 161 and 162.

According to the above-described embodiment, the number of capacitors that constitute the capacitor parts 60, 60A, 60B, 161 and 162 may be arbitrarily set as long as it is 2 or larger.

The process at step S104 is executed at each communication period T according to the first embodiment. However, the charge-discharge time Tc, Td can be identified with an interrupt in response to low level signal L outputted by the differential amplifier 53.

According to the present embodiment, the failure detecting unit 44 may measure the voltage of the signal Vi at a time when starting the output of the detection signal and the voltage of the signal Vi at a time when a predetermined period elapses from a time when the detection signal is caused to be outputted, thereby measuring the voltage change amount. Then, the failure detecting unit 44 may be configured to compare the voltage change amount and the threshold to detect a short-circuit.

The control unit and method thereof disclosed in the present disclosure may be accomplished by a dedicated computer constituted of a processor and a memory programmed to execute one or more functions embodied by computer programs. Alternatively, the control unit and method thereof disclosed in the present disclosure may be accomplished by a dedicated computer provided by a processor configured of one or more dedicated hardware logic circuits. Further, the control unit and method thereof disclosed in the present disclosure may be accomplished by one or more dedicated computer where a processor and a memory programmed to execute one or more functions, and a processor configured of one or more hardware logic circuits are combined. Furthermore, the computer programs may be stored, as instruction codes to be executed by the computer, into a computer readable non-transitory tangible recording media.

While the present disclosure has been described in accordance with the examples, the present disclosure should be understood such that the present disclosure is not limited to the examples and structures. The present disclosure also includes various modifications and modifications within an equivalent range. Additionally, various combinations and forms, as well as other combinations and forms further including only one element, more, or less, also fall within the category and scope of the present disclosure.

### CONCLUSION

The present disclosure provides a failure detecting apparatus capable of detecting a short-circuit failure with a simple configuration, and a failure detecting method thereof.

A failure detecting apparatus according to the present disclosure is provided in a reception apparatus that receives an AC signal from a transmission apparatus via a communication path, detecting a failure of a capacitor part provided on the communication path, wherein the capacitor part is configured of a plurality of capacitors connected in series to cutoff DC current, the failure detecting apparatus including: a signal input part that receives a predetermined detection signal from the transmission apparatus; and a detection part that detects, based on a voltage change amount of the detection signal received by the signal input part, a short-circuit failure of any of the capacitors that constitute the capacitor part.

The capacitor part is configured of a plurality of capacitors connected in series. In the case where a short-circuit failure occurs on any one of the capacitors, the total capacitance of the capacitor part increases and the time constant in the charging or discharging increases. As a result, when a predetermined detection signal is applied to the capacitor, the voltage gradually increases.

Accordingly, the detection part is able to detect, based on the voltage change amount of the detection signal, a short-circuit failure of any one of capacitors that constitute the capacitor part. In other words, a circuit for failure detection is not required to be provided in the reception apparatus. Hence, the failure detection can be accomplished with a simple configuration.

Further, in the capacitor part, even when a short-circuit failure occurs on any of the capacitors, DC current can be continuously cutoff.

What is claimed is:

1. A failure detecting apparatus provided in a reception apparatus that receives an AC signal from a transmission apparatus via a communication path, detecting a failure of a capacitor part provided on the communication path, wherein the capacitor part is configured of a plurality of capacitors connected in series to cut off DC current, the failure detecting apparatus comprising:
a signal input part that receives a predetermined detection signal from the transmission apparatus; and
a detection part that detects, based on a voltage change amount of the detection signal received by the signal input part, a short-circuit failure of any of the capacitors that constitute the capacitor part.

2. The failure detecting apparatus according to claim 1,
wherein
the detection part is configured to determine that a short-circuit failure has occurred when a voltage change amount from a time when starting the output of the detection signal reaches a predetermined amount.

3. The failure detecting apparatus according to claim 2,
wherein
the transmission apparatus is configured to output a high level signal and a low level signal;
the reception apparatus includes a signal determination unit configured to determine that a high level signal is received when a signal received by the signal input part is higher than or equal to a threshold voltage and determine that a low level signal is received when the signal received by the signal input part is less than the threshold voltage;
the detection part determines that a short-circuit failure has occurred in the case where a period from a time when the transmission apparatus is caused to output a high level signal as the detection signal to a time when the signal determination unit determines that a low level signal is received, is larger than a predetermined period, or in the case where a period from a time when the transmission apparatus is caused to output a low level signal as the detection signal to a time when the signal determination unit determines that a high level signal is received, is larger than or equal to a predetermined period.

4. The failure detecting apparatus according to claim 2,
wherein
the transmission apparatus is configured to alternately output, as the detection signal, a high level signal and a low level signal at a predetermined period;
the reception apparatus includes a signal determination unit configured to determine that a high level signal is received when a signal received by the signal input part is higher than or equal to a threshold voltage and determine that a low level signal is received when the signal received by the signal input part is less than the threshold voltage, and a logic determination unit configured to acquire a determination result of the signal determination unit at a sampling timing which is set based on a transition timing of a signal received by the signal input part and a communication period, and determine, based on the determination result, whether the transmission apparatus outputs which one of the high level signal or the low level signal; and
the detection part gradually changes the communication period when causing the transmission apparatus to output the detection signal, identifies an inversion timing at which a determination result of the logic determination unit is inverted and identifies a period required for the voltage change amount to reach a predetermined amount with a communication period in which the inversion timing is present.

5. The failure detecting apparatus according to claim 3 further comprising a threshold setting unit,
wherein
in a failure detection, the threshold setting unit is configured to set the threshold to be higher when causing the transmission apparatus to output the high level signal and to set the threshold to be lower when causing the transmission apparatus to output the low level signal

6. The failure detecting apparatus according to claim 1,
wherein
a plurality of the communication paths are present between the transmission apparatus and the reception apparatus;
a selection unit that selects one of the plurality of communication paths in a failure detection is provided;
the signal input part receives, in the failure detection, the detection signal from the transmission apparatus via the communication path selected by the selection unit;
the detection unit detects, in the failure detection, a short-circuit failure on any of the capacitors that constitute the capacitor part on the communication path selected by the selection unit, based on a voltage change amount of the detection signal received by the signal input part.

7. The failure detecting apparatus according to claim 1,
wherein
a pair of communication paths are provided between the transmission apparatus and the reception apparatus;
the transmission apparatus and the reception apparatus are configured to perform a differential communication via the pair of communication paths;
the signal input part receives the detection signal from the transmission apparatus via the pair of communication paths;
the detection unit detects a short-circuit failure on any of the capacitors that constitute the capacitor part on the pair of communication paths, based on a voltage change amount of the detection signal received by the signal input part.

8. The failure detecting apparatus according to claim 1,
wherein
in the case where three or more capacitors that constitute the capacitor part are present, the detection part detects, based on the voltage change amount, the number of capacitors in which a short-circuit-failure has occurred.

9. A failure detecting method performed by a failure detecting apparatus provided in a reception apparatus that receives an AC signal from a transmission apparatus via a communication path, detecting a failure of a capacitor part provided on the communication path, wherein the capacitor part is configured of a plurality of capacitors connected in series to cutoff DC current, the method comprising steps of:
a signal input step that receives a predetermined detection signal from the transmission apparatus via the communication path; and
a detection step that detects, based on a voltage change amount of the detection signal received by the signal input step, a short-circuit failure of any of the capacitors that constitute the capacitor part.
